(19) United States
(12) Patent Application Publication
(10) Pub. No.: US 2004/0170003 A1
(43) Pub. Date: Sep. 2, 2004

(54) Adjustable cassette for substrates

(76) Inventors: Yung-Chang Chen, Miao-Li (TW); Jia-Pang Pang, Miao-Li (TW); Chien-Ting Lai, Miao-Li (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/788,517

(22) Filed: Feb. 27, 2004

(30) Foreign Application Priority Data
Feb. 27, 2003 (TW) 92203126

(51) Int. Cl. G02F 1/1335; H05K 1/14

(52) U.S. Cl. 361/741

(57) ABSTRACT

A cassette (50) for holding or transporting substrates therein includes a pair of frames (51, 52) opposite each other, a pair of side plates (53, 54) facing each other and supporting the frames, and at least two division plates (55, 56) between the frames. The side plates include inner surfaces and supporting members (531) protruding from the inner surfaces, and the division plates also have supporting members protruding therefrom. The frames, the side plates and the division plates define at least three spaces for holding differently sized substrates on the supporting members.

### BACKGROUND OF THE INVENTION

1. Field of the Invention

The present invention relates to a cassette for holding or transporting a plurality of substrates therein, particularly substrates such as liquid crystal panels.

2. Prior Art

Nowadays, various kinds of substrates including glass substrates for LCDs (Liquid Crystal Displays), plasma displays and hybrid ICs (Integrated circuits) are extensively used. These substrates are generally loaded into a substrate cassette for storage or transportation. The cassette can conveniently hold a plurality of the substrates, and hence has been widely used for carrying the substrates from one fabrication shop floor to another.

A conventional cassette is shown in FIG. 3. The cassette 10 includes a top frame 11, a bottom frame 12, and two side plates 13 interconnecting the top frame 11 and the bottom frame 12. The two side plates 13 have parallel supporting members 131 protruding inwardly therefrom. The top frame 11, the bottom frame 12 and the side plates 13 cooperatively form a space 16, for accommodating substrates inserted along the supporting members 131. The cassette 10 also includes several stopper rods 15 for retaining substrates therein.

However, there may be various sizes of the substrates. When differently sized substrates need to be transported, a new cassette for each size of substrate is needed. This increases the costs of transportation.

Referring to FIG. 4, a cassette 20 for holding and transporting substrates of varying sizes is shown. The cassette 20 includes a top frame 21, a bottom frame 22, a side frame 27, a fixed side plate 23, and a moveable side plate 24. The side plates 23, 24 have parallel supporting members 231 protruding inwardly therefrom. The frames 21, 22, and the side plates 23, 24 cooperatively form a space 26 to accommodate substrates therein. The top frame 21 has two parallel grooves 211, and bottom frame 22 has two corresponding parallel grooves 221. The moveable side plate 24 can be slid along the grooves 211, 221 in order to adapt to new differently sized substrates. The moveable side plate 24 is fixed in a desired position by screws 30.

The cassette 20 can adjust the size of the space 26 in order to adapt to variations in sizes of the substrates, by moving the moveable side plate 24 along the frames 21, 22 and fixing the moveable side plate 24 in its new position. However, another space between the moveable side plate 24 and the side frame 27 is wasted. The efficiency of utilization of space is low.

Therefore, it is desired to provide a new cassette which overcomes the above-described disadvantages of conventional cassettes.

### SUMMARY OF THE INVENTION

An object of the present invention is to provide a cassette for holding or transporting a plurality of substrates, the cassette providing highly efficient utilization of space.

In order to achieve the above-described object, a cassette in accordance with the present invention includes a pair of frames opposite each other, a pair of side plates facing each other and supporting the frames, and at least two division plates between the frames. The side plates includes inner surfaces and supporting members protruding from the inner surfaces, and the division plates also have supporting members protruding therefrom. The frames, the side plates and the division plates define at least three spaces for holding differently sized substrates on the supporting members of the side plates and the division plates.

Other objects, advantages, and novel features of the present invention will be apparent from the following detailed description of preferred embodiments thereof with reference to the attached drawings, in which:

### BRIEF DESCRIPTION OF THE DRAWINGS

FIG. 1 is an isometric view of a cassette according to the present invention;

FIG. 2 is a cross-sectional view taken along line II-II of FIG. 1, and showing four substrates received in the cassette;

FIG. 3 is an isometric view of a conventional cassette; and

FIG. 4 is an isometric view of another conventional cassette.

### DETAILED DESCRIPTION OF THE PRESENT INVENTION

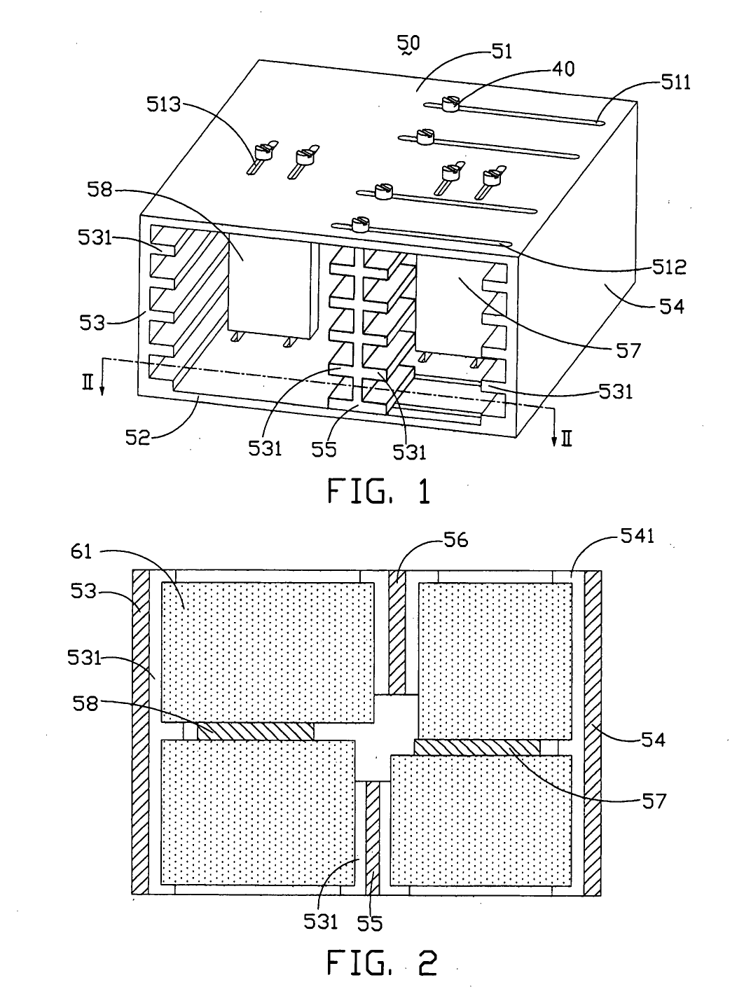

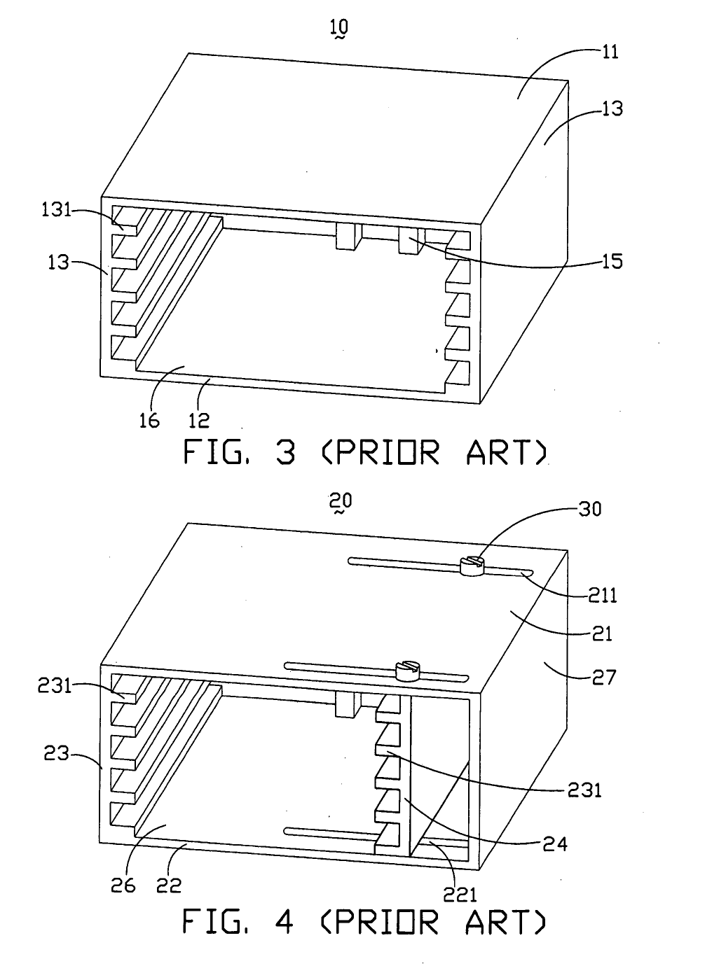

Referring to FIGS. 1 and 2, a cassette 50 for holding and transporting substrates therein includes a top frame 51, a bottom frame 52, a pair of side plates 53, 54, four division plates 55, 56, 57, 58, and a plurality of screws 40.

The top frame 51 and the bottom frame 52 are spaced away from each other and interconnected by the two side plates 53, 54. The frames 51, 52 have slide grooves 511 defined therein, the slide grooves 511 of the top frame 51 corresponding to the slide grooves 511 of the bottom frame 52.

The side plates 53, 54 have respective inner surfaces (not labeled), and a plurality of parallel supporting members 531 protruding inwardly from the inner surfaces.

The division plates 55, 56 are arranged parallel to the side plates 53, 54, and the division plates 57, 58 are arranged perpendicular to the side plates 53, 54. Parallel supporting members 531 protrude from each of side walls (not labeled) of the division plates 55, 56.

The frames 51, 52, the side plates 53, 54 and the division plates 55, 56, 57, 58 cooperatively form four receiving rooms (not labeled). FIG. 2 shows the cassette 50 holding four substrates 61 therein. The cassette 50 holds the substrates 61 on the supporting members 531 of the side plates 53 and the division plates 55, 56, the substrates 61 having different sizes. The division plates 55, 56, 57, 58 can be slid to various desired positions along the corresponding slide grooves 511, and fixed thereat by tightening corresponding screws 40 in the slide grooves 511. When the screws 40 are loosened, the division plates 55, 56, 57, 58 become freely movable along the slide grooves 511. It is convenient to adjust the positions of the division plates 55, 56, 57, 58 by loosening and tightening the corresponding screws 40, in order to enable the cassette 50 to hold various differently sized substrates 61. The efficiency of utilization of space by the cassette 50 is high.

In an alternative embodiment, only two division plates are provided between the frames 51 52. One of the division plates is parallel to the side plates 53, 54, and the other division plate is perpendicular to the side plates 53, 54. The frames 51 52, the side plates 53, 54 and the division plates cooperatively form three receiving rooms for holding substrates 61 having various sizes. The efficiency of utilization of space is high.

In summary, the advantages of the described embodiments are that the cassette provides at least three receiving rooms for holding and transporting substrates therein, and each receiving room can be easily adjusted to accommodate substrates 61 of various sizes by moving and fixing the division plates. The cassette can hold a plurality of substrates 61 of various sizes at any one time, and the efficiency of utilization of space is high.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cassette for supporting substrates, comprising:
a pair of frames;
a pair of side plates facing each other and interconnecting the frames, the side plates comprising supporting members protruding inwardly; and
at least two division plates disposed between the frames, the division plates having supporting members protruding therefrom;
wherein the frames, the side plates and the division plates define at least three spaces for holding substrates on the supporting members.

2. The cassette as claimed in claim 1, wherein the frames define mutually corresponding grooves therein.

3. The cassette as claimed in claim 1, further comprising a plurality of screws.

4. The cassette as claimed in claim 2, wherein the division plates can freely move along the grooves.

5. The cassette as claimed in claim 3, wherein the division plates are fixed to the frames by tightening the screws disposed in the grooves of the frames.

6. A cassette for supporting substrates during storage or transportation, comprising:
a pair of frames opposite to each other;
a pair of side plates facing each other and interconnecting the frames; and
four division plates between the frames;
wherein the frames, the side plates and the division plates define four spaces for holding substrates therein.

7. The cassette as claimed in claim 6, wherein the side plates and the division plates comprise supporting members protruding therefrom.

8. A cassette assembly comprising:
a pair of opposite horizontal frames;
a pair of opposite vertical side walls located between said pair of frames and cooperating with said pair of frames to define a large space therein;
at least one dividing plate attached between said pair of frames in said space so as to form two complementary sub-spaces in said space; and
two sets of supporting members located on inner sides of said pair of side plates and opposite sides of said dividing plate so as to receive different sized substrates in said two complementary sub-spaces.

9. The assembly as claimed in claim 8, wherein said dividing plate is moveable relative to the frames, and thus said complementary sub-spaces are variable.

10. The assembly as claimed in claim 9, wherein said dividing extends in a first direction while is moveable in a second direction perpendicular to said first direction.

11. The assembly as claimed in claim 9, wherein there are more than one dividing plates in said space, of which two extend in different directions mutually.

12. The assembly as claimed 11, wherein some of said more than one dividing plates have no supporting members on two opposite sides thereof.

13. The assembly as claimed in claim 9, wherein said dividing plate extends parallel to the side plates.

14. The assembly as claimed in claim 12, wherein said some dividing plates without supporting members thereon, extend perpendicular to the side plates.
